(19) United States
(12) Patent Application Publication
(10) Pub. No.: US 2020/0168800 A1
(43) Pub. Date: May 28, 2020

(54) MASK FRAME ASSEMBLY AND METHOD FOR MANUFACTURING MASK FRAME ASSEMBLY

(71) Applicant: SAMSUNG DISPLAY CO., LTD., Yongin-si (KR)

(72) Inventors: Jongyoon LEE, Yongin-si (KR); Jongbum KIM, Yongin-si (KR)

(21) Appl. No.: 16/595,630

(22) Filed: Oct. 8, 2019

(30) Foreign Application Priority Data
Nov. 28, 2018 (KR) 10-2018-0149513

(51) Int. Cl. H01L 51/00; C23C 14/04; H01L 51/56

(52) U.S. Cl. CPC H01L 51/0011; H01L 51/56; H01L 51/001; C23C 14/042

(57) ABSTRACT

Provided is a mask frame assembly. The mask frame assembly includes a stage provided with a seating part having a top surface, a frame on the seating part and having a bottom surface contacting the top surface seating part, and a mask on the frame. At least one of the top surface of the seating part and the bottom surface of the frame is an uneven surface.

### CROSS-REFERENCE TO RELATED APPLICATION

Korean Patent Application No. 10-2018-0149513, filed on Nov. 28, 2018, in the Korean Intellectual Property Office, and entitled: “Mask Frame Assembly and Method for Manufacturing Mask Frame Assembly,” is incorporated by reference herein in its entirety.

### BACKGROUND

### 1. Field

The present disclosure herein relates to a mask frame assembly and a method for manufacturing the mask frame assembly.

### 2. Description of the Related Art

In general, in organic light emitting display devices, an organic layer and/or an electrode are/is formed by a vacuum deposition method. As organic light emitting display devices increase in resolution, openings in a mask used in the deposition process to manufacture the organic light emitting device decrease in size and spacing therebetween.

The mask may thermally expand during the deposition process and/or be deformed by its own weight. Thus, a shadow effect may occur.

### SUMMARY

An embodiment provides a mask frame assembly including: a stage having a seating part with a top surface; a frame on the seating part and having a bottom surface contacting the top surface the seating part; and a mask on the frame. At least one of the top surface of the seating part and the bottom surface of the frame being an uneven surface.

In an embodiment, the uneven surface may be a laser textured surface.

In an embodiment, the uneven surface may be a plasma nitride surface.

In an embodiment, the mask frame assembly may further include a stick part between the frame and the mask.

In an embodiment, the stick part may include a first stick extending in a first direction.

In an embodiment, thermal deformation force of the first stick may be less than or equal frictional force between the seating part and the frame.

In an embodiment, the stick part may further include a second stick extending in a second direction crossing the first direction.

In an embodiment, thermal deformation force of the second stick may be less than or equal frictional force between the seating part and the frame.

In an embodiment, the bottom surface may be parallel to a bottom surface of the mask.

In an embodiment, a static friction coefficient between the seating part and the bottom surface may be 1 or more.

In an embodiment, the mask frame assembly may further include a spacer on the mask.

In an embodiment, the mask frame assembly may further include a magnet on the mask.

In an embodiment, the frame may include invar.

In an embodiment, an opening may be defined in the frame.

In an embodiment, the frame may have a rectangular ring shape.

In an embodiment, a method for manufacturing a mask frame assembly includes: preparing a stage having a seating part with a top surface; preparing a frame having a bottom surface; forming an uneven surface on one of the top surface of the seating part and the bottom surface of the frame; disposing the frame on the stage so that the bottom surface directly contacts the top surface of the seating part; and disposing a mask on a top surface of the frame.

In an embodiment, the method may further include reinforcement processing on the uneven surface.

In an embodiment, reinforcement processing may include plasma nitriding processing.

In an embodiment, forming the bottom surface includes irradiating a laser beam.

In an embodiment, the laser beam may have a pulse period of about 15 μm to about 25 μm.

### BRIEF DESCRIPTION OF THE DRAWINGS

Features will become apparent to those of skill in the art by describing in detail exemplary embodiments with reference to the attached drawings in which:

FIG. 1 illustrates a perspective view of a mask frame assembly according to an embodiment;

FIG. 2 illustrates an exploded perspective view of the mask frame assembly according to an embodiment;

FIG. 3 illustrates a cross-sectional view of the mask frame assembly according to an embodiment;

FIG. 4 illustrates an enlarged cross-sectional view of an area AA′ of FIG. 3 according to an embodiment;

FIG. 5 illustrates a flowchart of a method for manufacturing a mask frame assembly according to an embodiment;

FIG. 6 illustrates a perspective view of forming an uneven bottom surface in FIG. 5 according to an embodiment;

FIG. 7 illustrates a cross-sectional view of a process of depositing a deposition layer on a substrate by using the mask frame assembly according to an embodiment;

FIG. 8 illustrates a cross-sectional view of a process of depositing a deposition layer on a substrate by using the mask frame assembly according to an embodiment;

FIG. 9 illustrates a cross-sectional view of a process of depositing a deposition layer on a substrate by using the mask frame assembly according to an embodiment;

FIG. 10 illustrates an exploded perspective view of a mask frame assembly according to an embodiment; and

FIG. 11 illustrates a cross-sectional view of an organic light emitting display device including a light emitting layer deposited by using the mask frame assembly according to an embodiment.

### DETAILED DESCRIPTION

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like reference numerals refer to like elements throughout. Also, in the figures, the thickness, ratio, and dimensions of components are exaggerated for clarity of illustration.

The term “and/or” includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in one embodiment can be referred to as a second element in another embodiment without departing from the scope of the appended claims. The terms of a singular form may include plural forms unless referred to the contrary.

Also, ““under”, “below”, “above’, “upper”, and the like are used for explaining relation association of components illustrated in the drawings. The terms may be a relative concept and described based on directions expressed in the drawings.

Unless otherwise defined, all terms (including technical and scientific terms) used herein have the same meaning as commonly understood by a person of ordinary skill in the art to which this disclosure belongs. Also, terms such as defined terms in commonly used dictionaries are to be interpreted as having meanings consistent with meaning in the context of the relevant art and are expressly defined herein unless interpreted in an ideal or overly formal sense.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

Hereinafter, exemplary embodiments will be described with reference to the accompanying drawings.

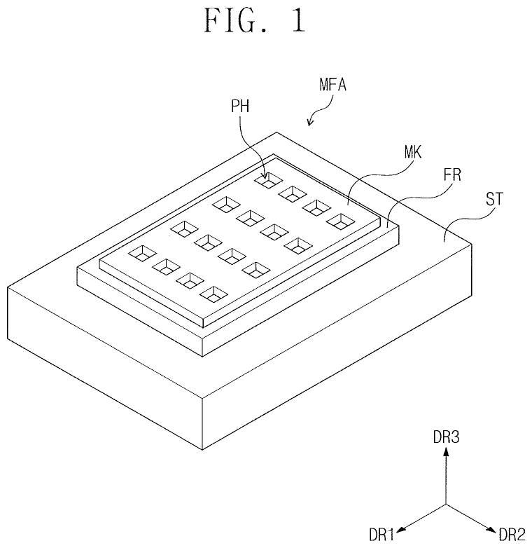

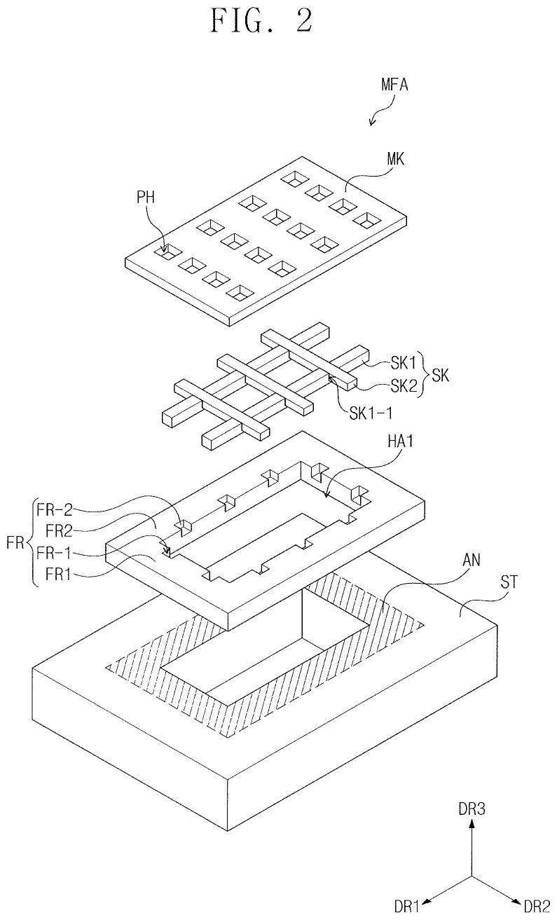

FIG. 1 is a perspective view of a mask frame assembly according to an embodiment and FIG. 2 is an exploded perspective view of the mask frame assembly according to an embodiment. Referring to FIGS. 1 and 2, a mask frame assembly MFA may include a mask MK, a stick part SK, a frame FR, and a stage ST.

The mask MK may be manufactured using a thin plate. The mask MK may be made of various materials, e.g., stainless steel, invar, nickel (Ni), cobalt (Co), a nickel alloy, a nickel cobalt alloy, and the like.

The mask MK may be parallel to a plane defined by a first direction DR1 and a second direction DR2. For example, the mask MK may have various shapes, e.g., a rectangular shape, that is parallel to the first direction DR1 and the second direction DR2. A vertical direction of the mask MK may correspond to a thickness direction (hereinafter, referred to as a third direction DR3) of the mask MK.

The directions indicated as the first to third direction DR1, DR2, and DR3 may be a relative. Hereinafter, the first to third directions may be directions indicated by the first to third direction DR1, DR2, and DR3 and designated by the same reference numerals, respectively. Also, in this specification, a surface defined by the first direction DR1 and the second direction DR2 may be defined as a plane, and “when viewed in the plane” may be defined as viewed in the third direction DR3.

Pattern holes PH may be defined in the mask MK. Each of the pattern holes PH may provide a path through which a deposition material passes. The pattern holes PH may expose areas of substrate CB (see FIG. 7) on which deposition will be performed. The pattern hole PH may have substantially the same shape as a deposited pattern to be formed on the plane or may have various shapes in accordance with characteristics of the deposition process to be performed there through. For example, in the pattern hole PH, a masking pattern may have individual openings or may have a stripe shape may be formed. The pattern hole PH may be provided in plurality. The plurality of pattern holes PH may form a matrix arranged in the first direction DR1 and the second direction DR2.

The stick part SK may be on a lower portion of the mask MK. The stick part SK may be on the lower portion of the mask MK to additionally support the mask MK. The stick part SK may overlap the mask MK on the plane. The stick part SK may not overlap the pattern hole PH on the plane.

The stick part SK may include a first stick SK1I and a second stick SK2. The first stick SK1 may extend in the first direction DR1. The first stick SK1I may be on a lower portion of the second stick SK2. A portion of the first stick SK1 may overlap a portion of the second stick SK2 on the plane, e.g., along the third direction D3. The first stick SK1 and the second stick SK2 may be have various shapes, e.g., a rectangular parallelepiped. The first stick SK1 may include a stick groove SK1-1. The stick groove SK1-1 may be coupled to the second stick SK2. The stick groove SK1-1 may be coupled to the second stick SK2 through welding. The stick groove SK1-1 may be provided in plurality, and the plurality of stick grooves SK1-1 may be spaced apart from each other in the first direction DR1. The number of stick grooves SK1-1 may correspond to that of second stick SK2. The stick groove SK1-1 have a thickness that is equal to a height of the second stick SK2. When the first stick SK1 and the second stick SK2 are coupled to each other, a top surface of the stick part SK, e.g., a surface facing the mask MK, is flat.

The second stick SK2 may extend in the second direction DR2. Each of the first stick SK1 and the second stick SK2 may have various lengths, e.g., the first stick SK1 may extend longer, shorter, or the same in the first direction DR1 than the second stick SK2 extends in the second direction D2. Each of the first stick SK1 and the second stick SK2 may be provided in plurality.

The frame FR may be below the mask MK to support the mask MK, e.g., between the mask MK and the stage ST. A portion of the mask MK may overlap a portion of the frame FR on the plane, e.g., along the third direction DR3. An opening HA1 may be defined in the frame FR and may correspond to a shape of the mask MK, while having a smaller area on the plane than the mask MK. The opening HA1 may provide a path through which the deposition material passes. The frame FR may have various shapes, e.g., rectangular ring shape. The frame FR may be made of various metals or metal alloys having a low thermal expansion coefficient, e.g., invar, stainless steel, and the like.

The frame FR may include a first frame portion FR1 and a second frame portion FR2 that are integral. The first frame portion FR1 may extend in the second direction DR2. The second frame portion FR2 may extend in the first direction DR1. The first frame portion FR1 and the second frame portion FR2 may have various lengths, e.g., the second frame portion FR2 may extend longer, shorter, or the same in the first direction DR1 than the first frame portion FR1 extends in the second direction D2.

A first coupling groove FR-1 may be defined in the first frame portion FR1. The first stick SK1 may be in the first coupling groove FR-1. The first coupling groove FR-1 and the first stick SK1 may be fixed to each other, e.g., welded. A portion of the first stick SK1 may overlap a portion of the first frame portion FR1 on the plane. The first coupling groove FR-1 may be provided in plurality spaced apart from each other in the second direction DR2. The number of first coupling grooves FR-1 may correspond to the number of first sticks SK1.

A second coupling groove FR-2 may be defined in the second frame portion FR2. The second stick SK2 may be in the second coupling groove FR-2. The second coupling groove FR-2 and the second stick SK2 may be fixed to each other, e.g., welded. A portion of the second stick SK2 may overlap a portion of the second frame portion FR2 on the plane. The second coupling groove FR-2 may be provided in plurality spaced apart from each other in the first direction DR1. The number of second coupling grooves FR-2 may correspond to the number of second sticks SK2.

The first coupling groove FR-1 may have a depth greater than that of the second coupling groove FR-2 such that the flat upper surface of the stick part SK. The stage ST may be below the frame FR, e.g., between the frame and a substrate to be processed. A seating part AN may be provided on the stage ST. The frame FR may be on, e.g., directly contact, the seating part AN.

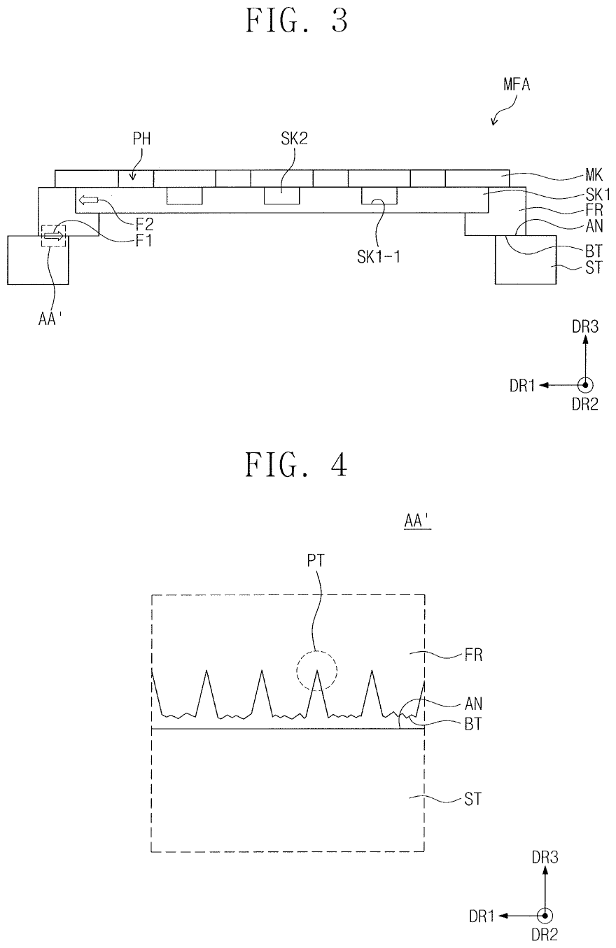

FIG. 3 is a cross-sectional view of the mask frame assembly according to an embodiment. The same reference numeral may be given to components that are the same as the components of FIGS. 1 and 2, and their detailed descriptions will be omitted.

Referring to FIG. 3, a bottom surface BT of the frame FR may directly contact a top surface of the seating part AN. The bottom surface BT may be parallel to the bottom surface of the mask MK. The bottom surface BT may include an uneven structure (see FIG. 4). Frictional force between the bottom surface BT and the stage ST may increase due the uneven structure PT. A static friction coefficient between the bottom surface BT and the top surface of the seating part AN may be 1 or more, e.g., stronger than the normal force. First force F may be frictional force generated between the bottom surface BT and the top surface of the seating part AN. Second force F2 may be thermal deformation force of the stick part SK and the mask MK. The first force F1 may be greater than or equal to the second force F2.

According to an embodiment, the second force F2 may be controlled by the first force F1, e.g., the first force F1 is strong enough to counter the second force F2. Thus, deformation of the stick SK due to thermal expansion may be prevented. Thus, deformation of the mask MK on the stick part SK may also be prevented. Thus, the shadow effect due to the deformation of the mask may be prevented from occurring. Therefore, the mask frame assembly MFA may be improved in reliability.

FIG. 4 is an enlarged cross-sectional view of an area AA′ of FIG. 3 according to an embodiment. The same reference numeral may be given to components that are the same as the components of FIGS. 1 to 3, and their detailed descriptions will be omitted.

Referring to FIGS. 3 and 4, the bottom surface BT may include the uneven structure PT. Alternatively or additionally, the top surface of the seating part AN may include the uneven structure. Each of the top surface of the seating part AN and the bottom surface BT having the uneven structure may be referred to as an uneven surface. Frictional force between the bottom surface BT and the top surface of the seating part AN increases due to the uneven structure PT. The uneven structure PT may be sufficiently uneven such that the first force F1 between the bottom surface BT and the top surface of the seating part AN offsets or controls the second force F2 to prevent deformation.

The uneven structure PT may be formed through laser surface texturing processing. The bottom surface BT may be a reinforced surface. The reinforcement processing may be plasma nitriding processing. The frictional force between the bottom surface BT and the top surface of the seating part AN may increase by the reinforcement processing.

If the frame FR is not flat, the mask MK may be deformed in shape. However, according to an embodiment, by providing an uneven bottom surface BT, a separate member is not used to increase in frictional force between the frame FR and the stage ST. Thus, the frame FR remains flat and the mask MK on the frame FR remains flat. Thus, the shadow effect due to the deformation of the mask MK may be prevented.

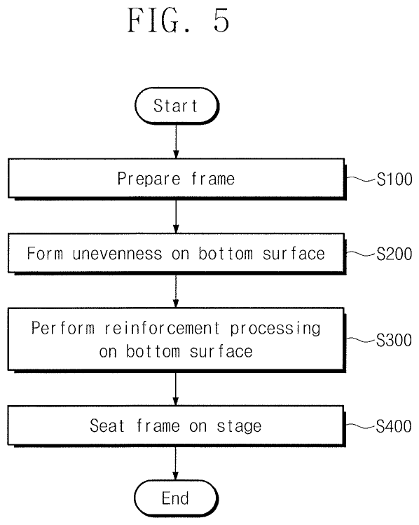

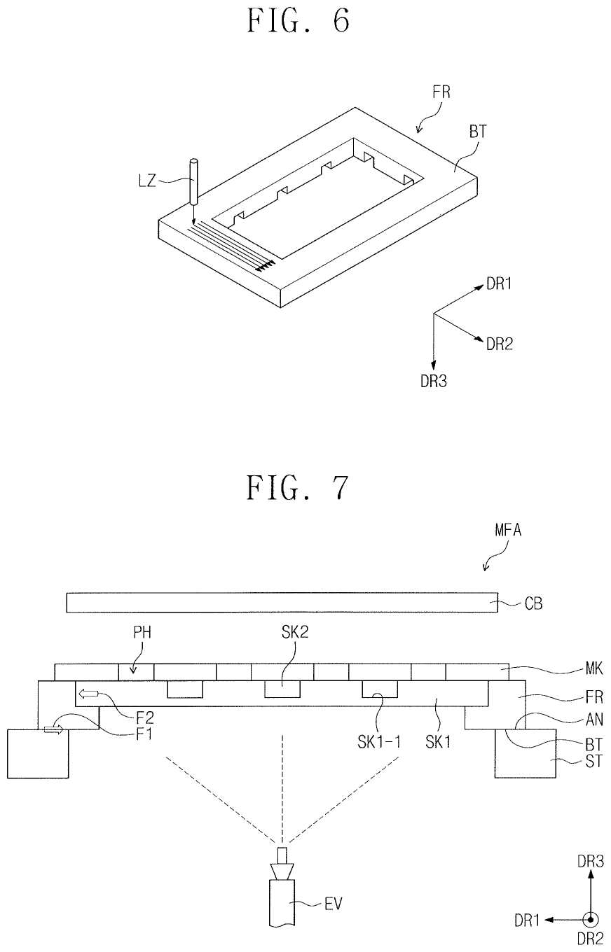

FIG. 5 is a flowchart illustrating a method for manufacturing a mask frame assembly according to an embodiment. FIG. 6 is a perspective view illustrating a process of forming an uneven bottom surface in FIG. 5 according to an embodiment. The same reference numeral may be given to components that are the same as the components of FIGS. 1 to 4, and their detailed descriptions will be omitted.

Referring to FIGS. 5 and 6, a method for manufacturing the mask frame assembly MFA (see FIG. 2) may include a frame preparation process (S100), a bottom surface unevenness formation process (S200), a bottom surface reinforcement processing process (S300), and a process (S400) of seating a frame on a stage.

The frame preparation process (S100) may include providing the frame (see FIG. 2).

The bottom surface unevenness formation process (S200) may be a process of forming an uneven structure PT (see FIG. 4) on a bottom surface BT (see FIG. 4) of the frame FR. The bottom surface unevenness formation process (S200) may include a process of irradiating a laser beam LZ onto the bottom surface BT to form the uneven structure PT may be formed on the bottom surface BT using the laser beam LZ (see FIG. 6). The uneven structure PT may be formed at various portions of the bottom surface BT, e.g., a single side extending in the second direction DR2, as long as the first force F1 between the bottom surface BT and the top surface of the seating part AN is sufficient to offset or controls the second force F2 to prevent deformation. Alternatively or additionally, an uneven structure may be formed on the top surface of the seating part AN of the stage ST.

The laser beam LZ may have a pulse period of about 50 m or less. For example, the laser beam LZ may have a pulse period of about 15 m to about 25 μm. The laser beam LZ may be irradiated onto the bottom surface BT to form the uneven structure PT (see FIG. 4). The uneven structure PT may improve frictional force between the bottom surface BT and a stage ST (see FIG. 4).

The bottom surface reinforcement processing process (S300) may include a plasma nitriding processing process. The plasma nitriding processing may be performed to allow the bottom surface BT to be hardened, thereby increasing in frictional force.

The process (S400) of seating the frame on the stage may include a process of disposing the frame FR on the stage ST (see FIG. 3). For example, the process (S400) of seating the frame on the stage may include a process of disposing the frame FR on the stage ST (see FIG. 3) so that the bottom surface BT directly contacts the top surface of the seating part AN.

FIG. 7 is a cross-sectional view illustrating a process of depositing a deposition layer on a substrate by using the mask frame assembly according to an embodiment. The same reference numeral may be given to components that are the same as the components of FIGS. 1 to 6, and their detailed descriptions will be omitted.

Referring to FIG. 7, a deposition source EV may be below the mask frame assembly MFA. A substrate CB may be above the mask MK. The deposition source EV may inject a deposition source toward the mask frame assembly MFA. The deposition material passing through the mask MK may be deposited on one surface of the substrate CB. The deposition material may be an organic light emitting layer of an organic light emitting display device. As the number of depositions using the deposition source EV increases, heat energy may be accumulated in a stick part SK (see FIG. 2) and the mask MK, and thermal deformation may occur. For example, the stick part SK and the mask MK may expand. Second force F2 represents the thermal deformation force. First force F1 represents frictional force between the frame FR and the stage ST, i.e., between the bottom surface BT and the top surface of the seating part AN.

According to an embodiment, the second force F2 may be offset by the first force F1. Thus, the expansion of the stick part SK (see FIG. 2) and the mask MK may be prevented. As a result, the deformation of the mask MK and, thus, a shadow effect may be prevented. Therefore, the mask frame assembly MFA (see FIG. 2) may be improved in process reliability.

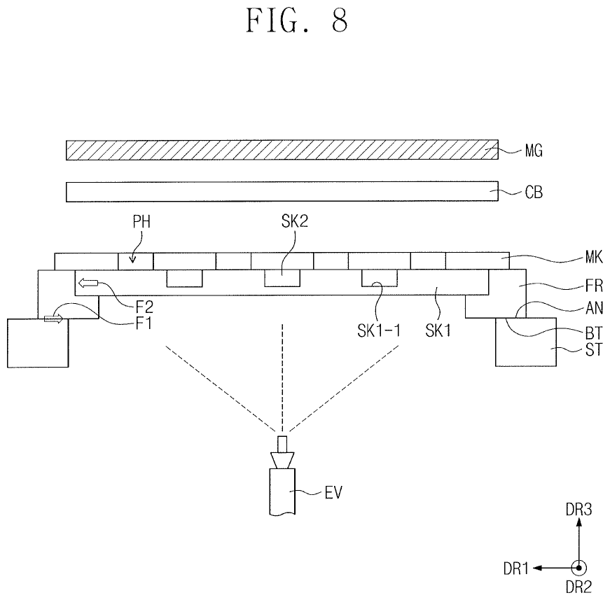

FIG. 8 is a cross-sectional view illustrating a process of depositing a deposition layer on a substrate by using the mask frame assembly according to an embodiment. The same reference numeral may be given to components that are the same as the components of FIGS. 1 to 7, and their detailed descriptions will be omitted.

Referring to FIG. 8, a magnet MG may be above the substrate CB such that the substrate CB is between and the mask MK. The magnet MG may prevent the mask MK from drooping downward under its own weight. The mask MK may be made of, e.g., nickel, a nickel alloy, and the like, and may have a thin film having magnetism thereon.

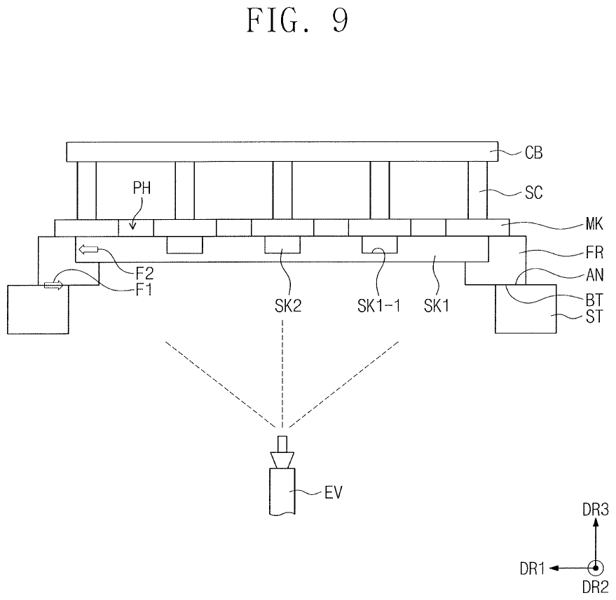

FIG. 9 is a cross-sectional view illustrating a process of depositing a deposition layer on the substrate by using the mask frame assembly according to an embodiment. Referring to FIG. 9, a spacer SC may be between the mask M and the substrate CB. The spacer SC may constantly maintain a distance between the mask MK and the substrate CB. The spacer SC may have various shapes, e.g., a pillar shape.

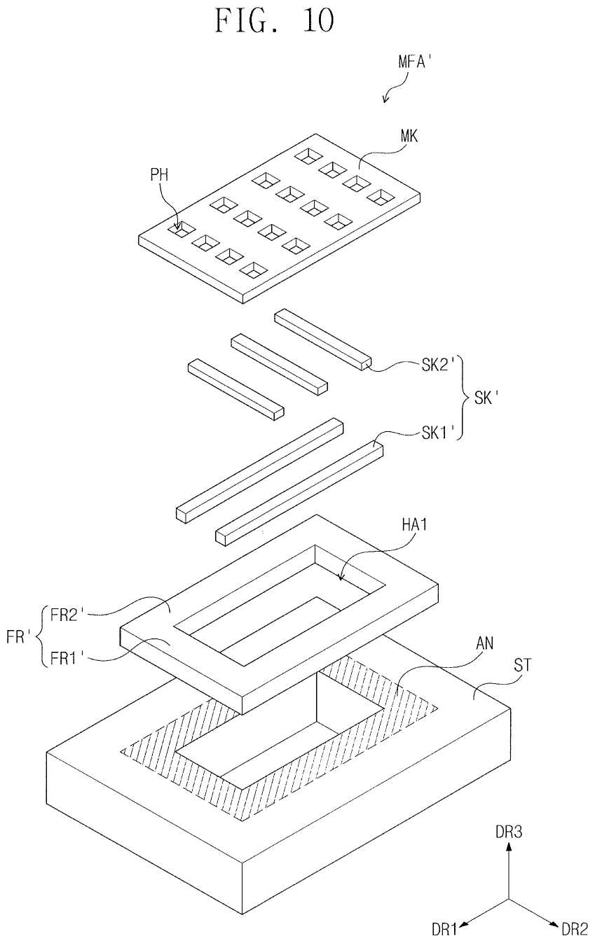

FIG. 10 is an exploded perspective view of a mask frame assembly according to an embodiment. The same reference numeral may be given to components that are the same as the components of FIGS. 1 to 9, and their detailed descriptions will be omitted.

Referring to FIG. 10, a mask frame assembly MFA′ may include the mask MK, a stick part SK′, a frame FR′, and the stage ST. The stick part SK′ may be on a lower portion of the mask MK. The stick part SK′ may be on the lower portion of the mask MK to additionally support the mask MK. The stick part SK′ may overlap the mask MK on the plane. The stick part SK′ may not overlap a pattern hole PH on the plane. As discussed above, a bottom surface of the frame FR′ that faces the stage ST may be uneven surface.

The stick part SK′ may include a first stick SK1′ and a second stick SK2′. The first stick SK1′ may extend in the first direction DR1. The first stick SK1′ and the second stick SK2′ may be have various shapes. e.g., a rectangular parallelepiped. The first stick SK1′ may be on a lower portion of the second stick SK2′. A portion of the first stick SK1′ may overlap a portion of the second stick SK2′ on the plane.

Each of the first stick SK1′ and the second stick SK2′ may have various lengths. For example, the first stick SK1′ may extend longer, shorter, or the same in the first direction DR1 than the second stick SK2′ extends in the second direction D2. Each of the first stick SK1′ and the second stick SK2′ may be provided in plurality. Each of a thickness of the first stick SK1′ in the third direction DR3 and a thickness of the second stick SK2′ in the third direction DR3 may be less than each of a thickness of the frame FR′ in the third direction and a thickness of the mask MK in the third direction DR3.

The frame FR′ may be below the mask MK. The frame FR′ may support the mask MK. A portion of the mask MK may overlap a portion of the frame FR′ on the plane. The opening HA1 may be defined in the frame FR′. The opening HA1 may provide a path through which the deposition material passes. The frame FR′ may have various shapes, e.g., rectangular ring shape. The frame FR′ may be made of various metals or metal alloys having a low thermal expansion coefficient, e.g., invar, stainless steel, and the like.

The frame FR′ may include a first frame portion FR1′ and a second frame portion FR2′. The first frame portion FR1′ may extend in the second direction DR2. The second frame portion FR2′ may extend in the first direction DR1. The first frame portion FR2′ may extend longer, shorter, or the same in the first direction DR1 than the first frame portion FR1′ extends in the second direction D2.

The first frame portion FR1′ may provide a flat top surface. The second frame portion FR2′ may provide a flat top surface. The stick part SK′ may be on a top surface of the frame FR′, e.g., the first stick SK1′ may extend further along the first direction DR1 than the second frame portion FR2′ and the second stick SK2′ may extend further along the second direction DR2 than the first frame portion FR1′. The frame FR′ and the mask MK may be spaced apart from each other along the third direction DR3 by the sum of the thickness of the first stick part SK1′ and the thickness of the second stick part SK2′.

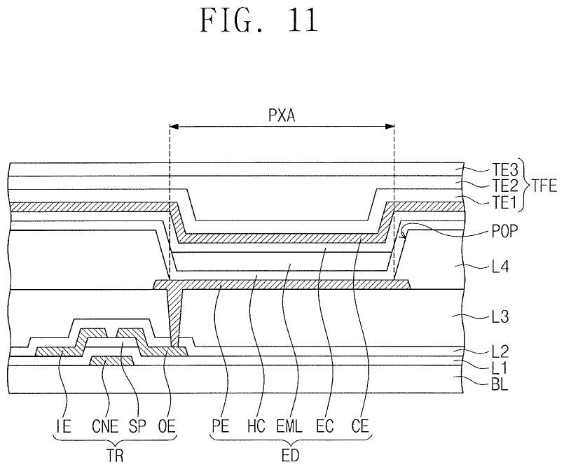

FIG. 11 is a cross-sectional view of an organic light emitting display device including a light emitting layer deposited by using the mask frame assembly according to an embodiment. Referring to FIG. 11, a base layer BL may be a silicon substrate, a plastic substrate, a glass substrate, an insulation film, a laminate structure including a plurality of insulation layers, and the like. The thin film transistor TR may include a control electrode CNE, an input electrode IE, an output electrode PE, and a semiconductor pattern SP.

The control electrode CNE may be on the base layer BL. The control electrode CNE may include a conductive material, e.g., a metal material. The metal material may include, for example, molybdenum, silver, titanium, copper, aluminum, alloys thereof, and the like.

A first insulation layer L1 may be on the base layer BL to cover the control electrode CNE. That is, the control electrode CNE may be between the first insulation layer L1 and the base layer BL.

The semiconductor pattern SP may be on the first insulation layer L1. The semiconductor pattern SP may be spaced apart from the control electrode CNE with the first insulation layer L1 therebetween in a cross-section.

The semiconductor pattern SP may include a semiconductor material, e.g., at least one of amorphous silicon, polycrystalline silicon, single crystal silicon, an oxide semiconductor, a compound semiconductor, and the like. The input electrode IE and the output electrode OE may be on the semiconductor pattern SP.

A second insulation layer L2 may be on the first insulation layer L1 to cover the semiconductor pattern SP, the input electrode IE, and the output electrode OE. That is, the semiconductor pattern SP, the input electrode IE, and the output electrode OE may be d between the first insulation layer L1 and the second insulation layer L2.

The third insulation layer L3 may be on the second insulation layer L2. For example, each of the first insulation layer L1 and the second insulation layer L2 may include an inorganic material, and the third insulation layer L3 may include an organic material. The third insulation layer L3 may provide a planarization surface.

A light emitting element ED may be an organic light emitting diode. The light emitting element ED may include a pixel electrode PE, a first auxiliary layer HC (or a hole control layer), a light emitting layer EML, a second auxiliary layer EC (or an electron control layer), and a common electrode CE.

The pixel electrode PE may be on a third insulation layer L3. A through-hole be defined in each of the second and third insulation layers L2 and L3. A portion of the output electrode OE may be exposed through the through-holes. The pixel electrode PE may be electrically connected to the exposed output electrode OE. For example, the pixel electrode PE may be an anode layer.

A fourth insulation layer L4 may be on the third insulation layer L3. The fourth insulation layer L4 may cover a portion of the pixel electrode PE and expose the other portion of the pixel electrode PE. The fourth insulation layer L4 may be a pixel defining layer. A pixel light emitting areas PXA may be defined to correspond to the pixel electrode PE exposed by the fourth insulation layer L4. An opening POP defining the pixel light emitting area PXA may be defined in the fourth insulation layer L4. The opening POP may be defined by removing a portion of the fourth insulation layer L4. In this specification, a portion of indication lines of the reference numerals of the openings are marked as indicating a side surface of the configuration defining the openings.

A common electrode CE is on the pixel electrode PE. The common electrode CE may include, for example, a cathode electrode. The common electrode CE may be made of a material having a low work function to facilitate electron injection.

The pixel electrode PE and the common electrode CE may be provided as a single layer or a multilayer. Each of the pixel electrode PE and the common electrode CE may include a conductive material. The conductive material may be a metal, an alloy, an electrically conductive compound, a mixture thereof, and the like. For example, each of the pixel electrode PE and the common electrode CE may include indium zinc oxide (IZO), indium tin oxide (ITO), indium gallium oxide (IGO), indium zinc gallium oxide (IGZO), and a mixture/compound thereof, molybdenum, silver, titanium, copper, aluminum, an alloy thereof, and the like.

The light emitting layer EML may be between the pixel electrode PE and the common electrode CE. The light emitting layer EML may have a single layer structure formed of a single material, a single layer structure formed of materials different from each other, or a multi-layered structure including a plurality of layers formed of materials different from each other.

The light emitting layer EML may include an organic material. The organic material is not specifically limited as long as the organic material is commonly used. For example, the light emitting layer EML may be made of at least one material of materials that emit light having red, green, and blue colors and include fluorescent material or a phosphorescent material. The light emitting layer EML may be a layer deposited by using the mask frame assembly described with reference to FIGS. 7 to 9.

A first auxiliary layer HC is between the pixel electrode PE and the light emitting layer EML. The first auxiliary layer HC may be a region through which holes injected from the pixel electrode PE pass to reach the light emitting layer EML.

The first auxiliary layer HC may include at least one of a hole injection layer, a hole transport layer, or a single layer having a hole injection function and a hole transport function at the same time. The first auxiliary layer HC may be made of at least one of the hole injection material or the hole transport material.

A second auxiliary layer EC is between the light emitting layer EML and the common electrode CE. The second auxiliary layer EC may be a region through which electrons injected from the common electrode CE pass to reach the light emitting layer EML.

The second auxiliary layer EC may include at least one of an electron injection layer, an electron transport layer, or a single layer having an electron injection function and an electron transport function at the same time. The second auxiliary layer EC may include at least one of an electron transport material or an electron injection material.

A thin film encapsulation layer TFE may be on the common electrode CE. The thin film encapsulation layer TFE may directly cover the common electrode CE. In an implementation, a capping layer covering the common electrode CE may be further between the thin film encapsulation layer TFE and the common electrode CE. In this case, the thin film encapsulation layer TFE may directly cover the capping layer. In an implementation, the thin film encapsulation layer TFE may be omitted.

The thin film encapsulation layer TFE may include a first inorganic layer TE1, an organic layer TE2, and a second inorganic layer TE3, which are sequentially laminated. The organic layer TE2 may be between the first inorganic layer TE1 and the second inorganic layer TE3. The first inorganic layer TE1 and the second inorganic layer TE3 may be formed by depositing an inorganic material, and the organic layer TE2 may be formed by depositing, printing, or applying an organic material.

The first inorganic layer TE1 and the second inorganic layer TE3 may protect the light emitting element ED from moisture and oxygen, and the organic layer TE2 may protect the light emitting element ED from foreign substances such as dust particles. The first inorganic layer TE1 and the second inorganic layer TE3 may include at least one of silicon nitride, silicon oxide nitride, silicon oxide, titanium oxide, aluminum oxide, and the like. For example, the organic layer TE2 may include an acrylic-based organic layer.

Although the thin film encapsulation layer TFE includes two inorganic layers and one organic layer in FIG. 11, the thin film encapsulation layer TFE may include three inorganic layers and two organic layers, and the like. In this case, the inorganic layers and the organic layers may be alternately laminated.

By way of summation and review, an uneven structure may be provided between the frame and the stage, e.g., a bottom surface of the frame and/or a top surface of the stage may be uneven surface. The frictional force between the frame and the stage may increase due to the unevenness. Even if the mask and the stick part supported by the frame thermally expand during the deposition process, the deformation of the mask may be prevented by the frictional force between the frame and the stage. Thus, the shadow effect due to the deformation of the mask may be prevented from occurring. Therefore, the mask frame assembly may be improved in reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A mask frame assembly, comprising:
a stage including a seating part having a top surface;
a frame on the seating part and having a bottom surface contacting the top surface of the seating part, at least one of the top surface of the seating part and the bottom surface of the frame being an uneven surface; and
a mask on the frame.

2. The mask frame assembly as claimed in claim 1, wherein the uneven surface is a laser textured surface.

3. The mask frame assembly as claimed in claim 1, wherein the uneven surface is a plasma nitride surface.

4. The mask frame assembly as claimed in claim 1, further comprising a stick part between the frame and the mask.

5. The mask frame assembly as claimed in claim 4, wherein the stick part includes a first stick extending in a first direction.

6. The mask frame assembly as claimed in claim 5, wherein thermal deformation force of the first stick is less than or equal to a frictional force between the seating part and the frame.

7. The mask frame assembly as claimed in claim 5, wherein the stick part further includes a second stick extending in a second direction crossing the first direction.

8. The mask frame assembly as claimed in claim 7, wherein thermal deformation force of the second stick is less than or equal frictional force between the seating part and the frame.

9. The mask frame assembly as claimed in claim 1, wherein the uneven surface is parallel to a bottom surface of the mask.

10. The mask frame assembly as claimed in claim 1, wherein a static friction coefficient between the seating part and the bottom surface is 1 or more.

11. The mask frame assembly as claimed in claim 1, further comprising a spacer on the mask.

12. The mask frame assembly as claimed in claim 1, further comprising a magnet on the mask.

13. The mask frame assembly as claimed in claim 1, wherein the frame includes invar.

14. The mask frame assembly as claimed in claim 1, wherein an opening is defined in the frame.

15. The mask frame assembly as claimed in claim 1, wherein the frame has a rectangular ring shape.

16. A method for manufacturing a mask frame assembly, the method comprising:
preparing a stage having a seating part with a top surface;
preparing a frame having a bottom surface;
forming an uneven surface on one of the top surface of the seating part and the bottom surface of the frame;
disposing the frame on the stage so that the bottom surface of the frame directly contacts the top surface of the seating part; and
disposing a mask on a top surface of the frame.

17. The method as claimed in claim 16, further comprising performing reinforcement processing on the uneven surface.

18. The method as claimed in claim 17, wherein reinforcement processing includes plasma nitriding processing.

19. The method as claimed in claim 16, wherein forming the uneven surface includes irradiating a laser beam.

20. The method as claimed in claim 19, wherein the laser beam has a pulse period of about 15 μm to about 25 μm.
